(19) United States
(12) Patent Application Publication
(10) Pub. No.: US 2022/0244301 A1
(43) Pub. Date: Aug. 4, 2022

(54) METHOD OF TESTING ACOUSTIC WAVE DEVICES

(71) Applicant: Skyworks Solutions, Inc., Irvine, CA (US)

(72) Inventors: Zhaogeng Xu, Irvine, CA (US); Toru Jibu, Irvine, CA (US); Chun Sing Lam, San Jose, CA (US)

(21) Appl. No.: 17/646,986

(22) Filed: Jan. 4, 2022

Related U.S. Application Data
(60) Provisional application No. 63/143,392, filed on Jan. 29, 2021.

(51) Int. Cl. G01R 31/00

(52) U.S. Cl. CPC G01R 31/002

(57) ABSTRACT

A method for improving the accuracy of a final inspection (FI) test of an acoustic wave device includes gating the feedthrough/cross-coupling (e.g., electromagnetic (EM) path) signal of the FI test data response for the tested acoustic wave device and adding a feedthrough/cross-coupling signal (e.g., EM path signal) from an engineering (EVB) test data (e.g., for a similar or identical surface acoustic device). This results in FI test data with time domain recovery of EM path signal from an EVB test, which can be compared against EVB test data (e.g. for a similar or identical surface acoustic device) to determine if the tested acoustic wave device passes inspection.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of this disclosure relate to acoustic wave devices and methods of testing such devices.

### Description of the Related Art

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

Acoustic wave filters undergo a final inspection prior to shipment. A tighter specification at final inspection (e.g., to lower an end product yield loss due to sensitivity in a particular cellular band) can unnecessarily lower the yield of operable acoustic wave devices during final inspection. Such tighter specification at final inspection can therefore result in the unnecessary disposal of operable acoustic wave devices that would otherwise have shipped to customers.

### SUMMARY

In accordance with one aspect of the disclosure, a method for improving the accuracy of the final inspection of an acoustic wave device is provided.

In accordance with one aspect of the disclosure, a method for improving the accuracy of a final inspection (FI) test of an acoustic wave device is provided. The method includes gating the feedthrough/cross-coupling signal (e.g., electromagnetic or EM path signal) of the final inspection (FI) test data for the acoustic wave device and adding a feedthrough/cross-coupling signal (e.g., EM path signal) from an EVB test data (e.g., for a similar or identical surface acoustic device). This results in FI test data with time domain recovery of EM path signal from an EVB test, which can be compared against EVB test data (e.g. for a similar or identical surface acoustic device) to determine if it meets operational specifications and can be approved for delivery to a customer.

In accordance with another aspect of the disclosure, a method for improving the accuracy of a final inspection (FI) test of an acoustic wave device is provided. The method includes gating the feedthrough/cross-coupling (e.g., electromagnetic (EM) path) signal in a time domain response of the final inspection (FI) test data for the acoustic wave device and adding a feedthrough/cross-coupling signal (e.g., EM path signal) from an EVB test data (e.g., for a similar or identical surface acoustic device). This results in FI test data with time domain recovery of EM path signal from an EVB test, which can be compared against EVB test data (e.g. for a similar or identical surface acoustic device) to determine if it meets operational specifications and can be approved for delivery to a customer.

In accordance with another aspect of the disclosure, a method for testing a performance of an acoustic wave device is provided. The method comprises performing a final inspection test on an acoustic wave device to obtain a test data response in a frequency domain. The method comprises also converting the final inspection test data response from the frequency domain to a time domain. The method also comprises gating an electromagnetic path signal of the final inspection test data response to produce a modified final inspection test data response without the electromagnetic path signal. The method also comprises adding an isolated electromagnetic path signal from an engineering test data response to the modified final inspection test data response to produce a final inspection test data response with time domain recovery of electromagnetic path signal from the engineering test.

In accordance with another aspect of the disclosure, a method for testing a performance of an acoustic wave device is provided. The method comprises performing an engineering test of a first acoustic wave device to obtain a test data response in a frequency domain. The method also comprises converting the engineering test data response from the frequency domain to a time domain. The method also comprises gating an electromagnetic path signal of the engineering test data response to isolate the electromagnetic path signal of the engineering test data response for the first acoustic wave device. The method also comprises performing a final inspection test on a second acoustic wave device to obtain a test data response in a frequency domain with units of the test data response in decibels versus frequency. The method also comprises converting the final inspection test data response from the frequency domain to a time domain with units of the test data response in decibels versus time in seconds. The method also comprises gating an electromagnetic path signal of the final inspection test data response to produce a modified final inspection test data response without the electromagnetic path signal. The method also comprises adding the isolated electromagnetic path signal of the engineering test data response for the first acoustic wave device to the modified final inspection test data response for the second acoustic wave device to produce a final inspection test data response with time domain recovery of the electromagnetic path signal from the engineering test.

### BRIEF DESCRIPTION OF THE DRAWINGS

FIG. 1 is a schematic diagram of test data for an acoustic wave device.

FIG. 2A is a graph of dB versus frequency for final inspection (FI) test data of an acoustic wave device.

FIG. 2B is a graph of dB versus time conversion of the test data of FIG. 2A.

FIG. 2C is an enlarged graph of a portion of the graph in FIG. 2B.

FIG. 3A is a graph of dB versus frequency for test data for an FI test versus an EVB test for an acoustic wave device.

FIG. 3B is a graph of dB versus time conversions of the test data of FIG. 3A for the FI test versus the EVB test.

FIG. 4 is a graph of dB versus frequency comparing EVB test data in FIG. 3A, EVB test data with time domain gating to remove EM path signal, and FI test data with time domain gating to remove EM path signal.

FIG. 5A is a flow chart of a time domain recovery method for FI test data for an acoustic wave device.

FIG. 5B is a flow chart of a time domain recovery method for FI test data for an acoustic wave device.

FIG. 6 is a graph of dB versus frequency comparing FI test data, EVB test data, and FI test data with time domain recovery of EM path signal from EVB test for an acoustic wave device.

FIG. 7 is a graph of dB versus frequency comparing FI test data, EVB test data, and FI test data with time domain recovery of EM path signal from EVB test for an acoustic wave device.

FIG. 8 a graph of dB versus frequency comparing FI test data, EVB test data, and FI test data with time domain recovery of EM path signal from EVB test for an acoustic wave device.

FIG. 9A is a graph of dB versus frequency comparing FI test data, EVB test data, and FI test data with time domain recovery of EM path signal from a standard EVB test for a first acoustic wave device.

FIG. 9B is a graph of dB versus time conversion of the FI test data, EVB test data, and FI test data with time domain recovery of EM path signal from a standard EVB test for the first acoustic wave device.

FIG. 10A is a graph of dB versus frequency comparing FI test data, EVB test data, and FI test data with time domain recovery of EM path signal from a standard EVB test for a second acoustic wave device.

FIG. 10B is a graph of dB versus time conversion of the FI test data, EVB test data, and FI test data with time domain recovery of EM path signal from a standard EVB test for the second acoustic wave device.

FIG. 11A is a schematic diagram of a transmit filter that includes a surface acoustic wave resonator according to an embodiment.

FIG. 11B is a schematic diagram of a receive filter that includes a surface acoustic wave resonator according to an embodiment.

FIG. 12 is a schematic diagram of a radio frequency module that includes a surface acoustic wave resonator according to an embodiment.

FIG. 13 is a schematic diagram of a radio frequency module that includes filters with surface acoustic wave resonators according to an embodiment.

FIG. 14 is a schematic block diagram of a module that includes an antenna switch and duplexers that include a surface acoustic wave resonator according to an embodiment.

FIG. 15A is a schematic block diagram of a module that includes a power amplifier, a radio frequency switch, and duplexers that include a surface acoustic wave resonator according to an embodiment.

FIG. 15B is a schematic block diagram of a module that includes filters, a radio frequency switch, and a low noise amplifier according to an embodiment.

FIG. 16A is a schematic block diagram of a wireless communication device that includes a filter with a surface acoustic wave resonator in accordance with one or more embodiments.

FIG. 16B is a schematic block diagram of another wireless communication device that includes a filter with a surface acoustic wave resonator in accordance with one or more embodiments.

FIG. 17 is a block diagram of a computer system with which certain systems and methods discussed herein may be implemented.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. The certain SAW devices may be referred to as SAW resonators. Any features of the SAW resonators discussed herein can be implemented in any suitable SAW device. An acoustic wave filter can be implemented with bulk acoustic wave (BAW) devices. The certain BAW devices may be referred to as BAW resonators. Any features of the BAW resonators discussed herein can be implemented in any suitable BAW device.

Acoustic wave devices, such as acoustic wave filters or resonators (e.g., SAW devices or resonators, BAW devices or resonators) undergo a final inspection (FI) following manufacture and prior to shipment to customers. FI testing of acoustic wave devices can be conducted using an existing testing apparatus, such as, in order of complexity and cost of use, a normal or conventional probe, a conductive sheet probe card, and a pyramid probe. An FI test is generally less complex and less expensive than an evaluation board (EVB) test (an engineering test) where the device to be tested is mounted (e.g., soldered) to a board (e.g., printed circuit board or PCB), due to the complexity of the componentry and test process used in an EVB test, though an EVB test is more accurate than an FI test. An EVB test can use a PCB (e.g., with two sided metal layers, or multiple metal layers with or without vias) and can have input and output traces to connectors (and/or have other matching components, such as an inductor or capacitor, mounted on the PCB). An EVB test can include one or more of the following steps: a) selecting a SAW/BAW die from a diced SAW/BAW wafer, b) coupling (e.g., solder) the SAW/BAW die on the EVB PCB, and c) testing the EVB PCB using a network analyzer (e.g., manually operated, or computer controlled network analyzer) to acquire the test data (e.g., automatically). Optionally, the EVB test can include storing the test data on a network analyzer, and transferring the test data to a computer. However, conducting an EVB test on all acoustic wave devices would be very expensive and could result in delays as common FI test tools are less costly and more widely available than EVB test tools.

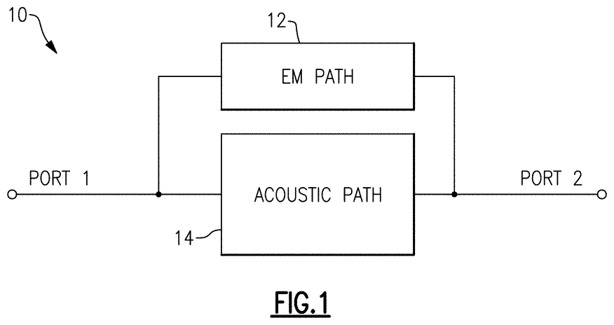

FIG. 1 shows a schematic diagram of test data 10 for a signal through an acoustic wave device (e.g., SAW device or resonator, BAW device or resonator), such as between port 1 and port 2. The signal includes an acoustic portion that passes through an acoustic path 14 and an electromagnetic (EM) or cross-coupling portion (i.e., non-acoustic signal) that passes through an EM path 12. The portion of the signal that passes through the acoustic path 14 has a relatively larger delay than the portion that passes through the EM path 12 (e.g., because the EM wave speed is approximately 100000 times faster than an acoustic wave). Therefore, EM path signal has a very short delay in the time domain, and lasts a short period of time, as compared to the acoustic path signal. Therefore, the total tested signal (St)includes the EM path signal (Sem) and the acoustic path signal (Sa), as provided by the formula below. The EM path signal (Sem) can be separated from the total tested signal (St) as discussed further below. The test data response, whether of an FI test or EVB test, both have an EM path signal and an acoustic path signal.

St=Sa+Sem

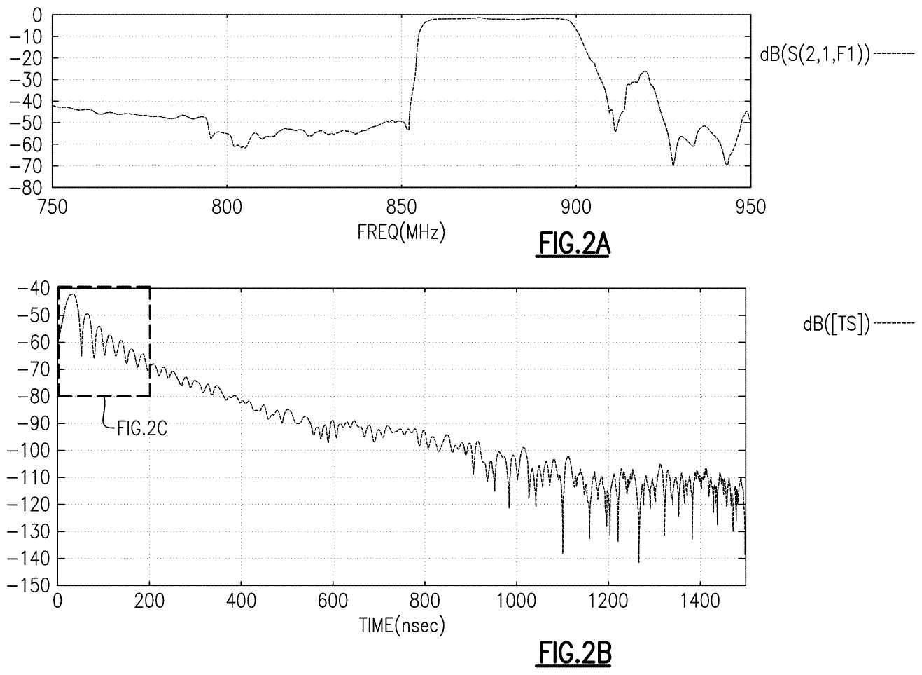

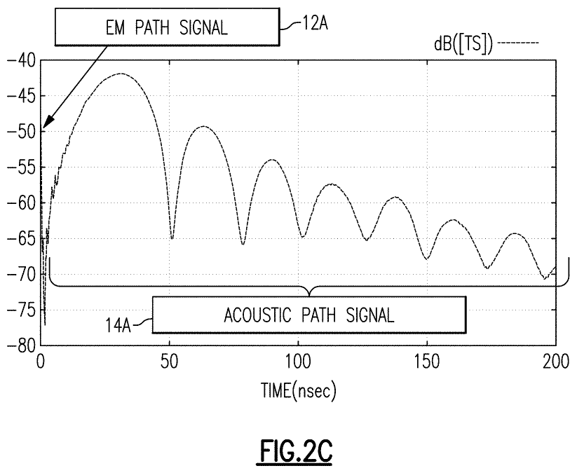

FIGS. 2A-2B show graphs of FI test data for an acoustic wave device. FIG. 2A shows the FI test data in the frequency domain, with acoustic power in decibels (dB) along the Y axis and frequency along the X axis. FIG. 2B shows the same FI test data as in FIG. 2A but converted to the time domain (by inverse Fourier transform), with decibels (dB) along the Y axis and time (in nanoseconds) along the X axis. FIG. 2C shows a magnification of a portion of the FI test data in the time domain shown in FIG. 2B. As indicated in FIG. 2C, the test data includes the EM path signal 12A, which occurs close to time 0 (e.g., at less than 5-10 nanoseconds), and the acoustic path signal 14A, which begins after the EM path signal and continues therefrom, which allows the gating off (or filtering off) of the EM path signal as further discussed below. Though FIGS. 2A-2B show the response for an FI test, a similar response (e.g., with the EM path signal occurring close to time 0 and the acoustic path signal continuing therefrom) would also be present in an EVB test. The test data is converted to the time domain (using inverse Fourier transform) to more easily identify the EM path signal and acoustic path signal and facilitate the gating of the EM path signal. Though the transition between the EM path signal and the acoustic path signal is device dependent, in one example the transition between the EM path signal and the acoustic path signal can be identified by the inflection point (e.g., minimum) in the acoustic response shortly after time 0 (e.g., in the first 5-10 nanoseconds) of the test.

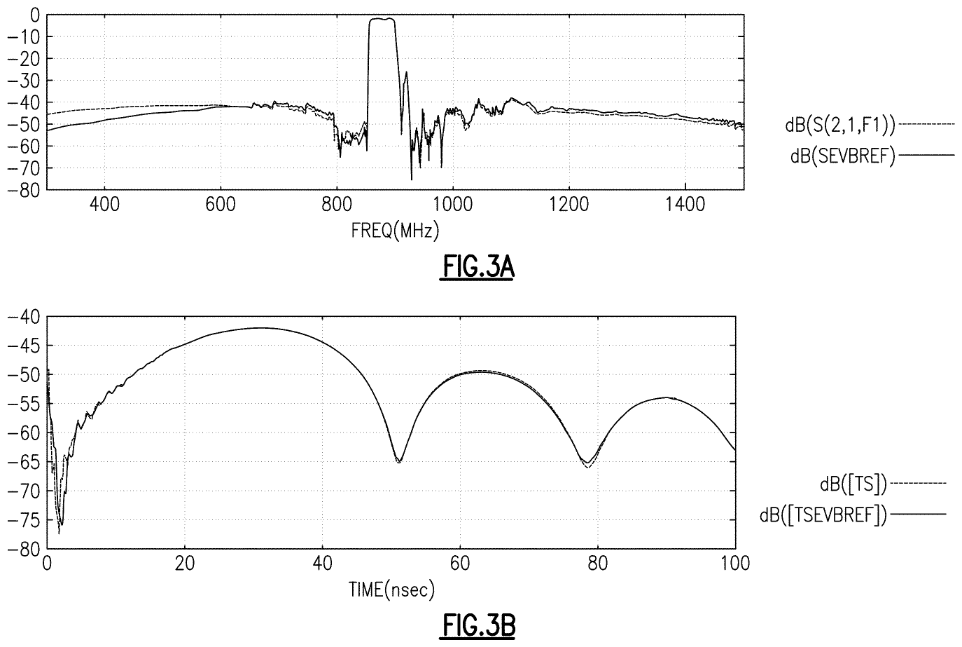

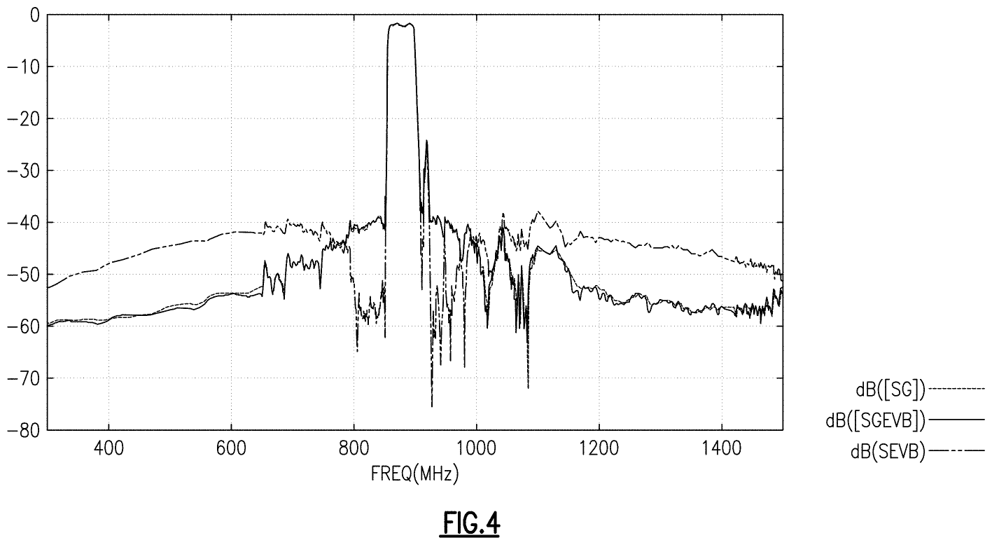

FIG. 3A-3B show graphs comparing test data from an FI test (dashed line) with test data from an EVB test (solid line) for the same acoustic wave device (e.g., SAW device or resonator, BAW device or resonator). FIG. 3A shows the comparison between the FI test data (e.g., performed with a pyramid probe) and EVB test data in the frequency domain, and FIG. 3B shows the comparison between the FI test data and EVB test data in the time domain (e.g., using inverse Fourier transform to convert from the frequency domain to the time domain). The FI test data response is shown in a dashed line, and the EVB test data response is shown in a solid line. The acoustic path signal of both the FI test data and EVB test data are similar (e.g., almost the same, particularly in the time domain graph of FIG. 3B), but there are differences closer to time 0 between the FI test data and the EVB test data due to the EM path signal.

FIG. 4 shows a comparison in the frequency domain for a tested acoustic wave device (e.g., a SAW device or resonator, a BAW device or resonator) of EVB test data (dash-dot-dot-dash line), FI test data following time domain gating to cut off EM path signal (dashed line), and EVB test data following time domain gating to cut off EM path signal (solid line). The time domain gating to cut off EM path signal was performed by first converting (using inverse Fourier transform) the frequency domain response for the FI test data and EVB test data to the time domain, after which the EM path signal was gated off (e.g., filtered out, removed) from said time domain response of the FI test data and EVB test data, following which the FI test data and EVB test data response in the time domain with the EM path signal gated off was converted back to frequency domain (using Fourier transform). As shown in FIG. 4, the responses for the FI test data with time domain gating to cut off the EM path signal and EVB test data with time domain gating to cut off the EM path signal are very similar (e.g., overlap). However, they still differ from the EVB test data response (dash-dot-dot-dash line), which is the more accurate test response. Therefore, gating off EM path signal does not result in the modified FI test data response (e.g., with time domain gating of EM path signal) correlating better (e.g., approximating) the EVB test data response for testing (e.g., FI and EVB tests) of the same acoustic wave device.

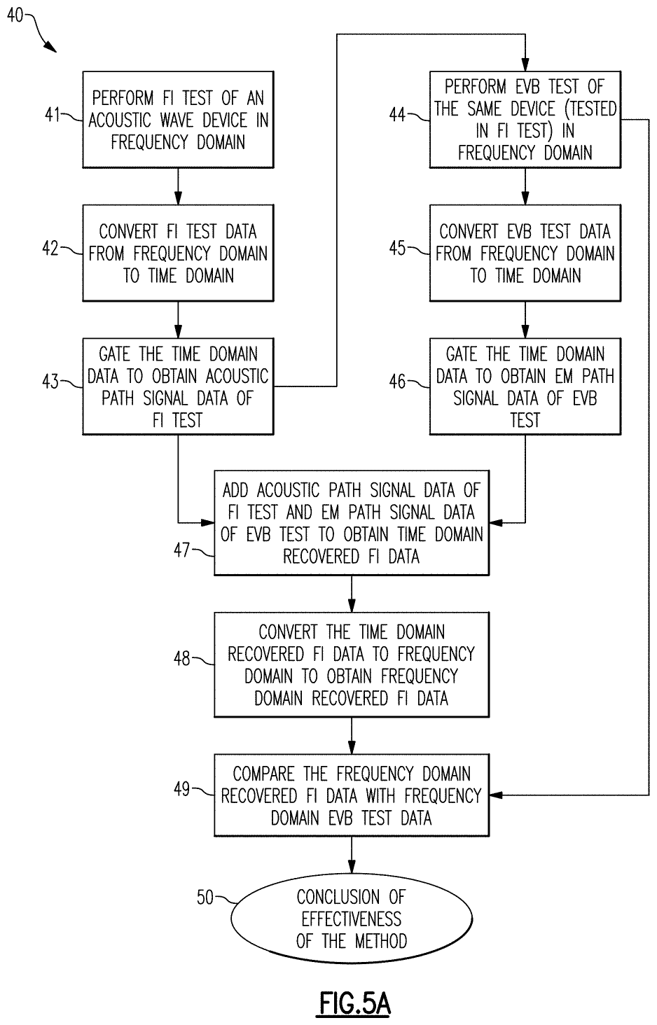

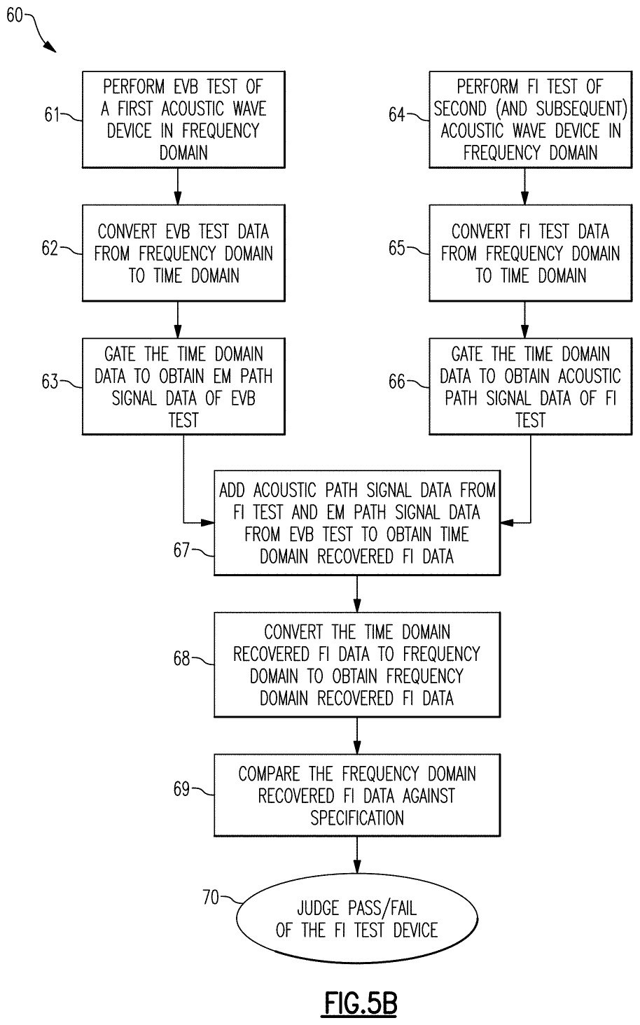

FIG. 5A is a flow chart of a time domain recovery method 40 for an acoustic wave device (e.g., a SAW device or resonator, a BAW device or resonator). The method 40 includes the step of performing 41 an FI test of an acoustic wave device (e.g., a SAW device or resonator, a BAW device or resonator) and obtain test data in the frequency domain. The method 40 also includes the step of converting 42 (e.g., using an inverse Fourier transform) the FI test data from the frequency domain to the time domain. The method 40 also includes the step of gating 43 (e.g., filtering out, removing) the EM path signal (e.g., feedthrough/cross-coupling signal) in the time domain from the FI test data response to obtain acoustic path signal data for the FI test. The method 40 also includes the step of performing 44 an EVB test of the same acoustic wave device (e.g., a SAW device or resonator, a BAW device or resonator) to obtain test data in the frequency domain. The method 40 also includes the step of converting 45 (e.g., using an inverse Fourier transform) the EVB test data from the frequency domain to the time domain. The method 40 also includes the step of gating 46 (e.g., filtering out, removing) the EM path signal (e.g., feedthrough/cross-coupling signal) in the time domain from the EVB test data response to isolate the EM path signal data of the EVB test. The method 40 also includes the step of adding 47 the isolated EM path signal data (e.g., feedthrough/cross-coupling signal) from the EVB test data to the acoustic path signal data (from step 43) to obtain a time domain recovered FI test data (e.g., acoustic path signal data of FI test with time domain recovery of EM path signal data from EVB test). The method 40 also includes the step of converting 48 the time domain recovered FI test data (using a Fourier transform) to frequency domain to obtain a frequency domain recovered FI test data (e.g., acoustic path signal data of FI test with time domain recovery of EM path signal data from EVB test). The method 40 also includes the step of comparing 49 the frequency domain recovered FI test data (acoustic path signal data of FI test with time domain recovery of EM path signal data from EVB test) with the frequency domain EVB test data (from step 44). The method 40 also includes the step of determining 50 the effectiveness of the frequency domain recovered FI data (e.g., acoustic path signal data of FI test with time domain recovery of EM path signal data from EVB test) based on how much the frequency domain recovered FI test data corresponds (e.g., overlaps, tracks) the frequency domain EVB test data. If the frequency domain recovered FI data corresponds (e.g., overlaps, tracks) the frequency domain EVB test data well, then frequency domain recovered FI data can be used as a standard or specification for subsequently tested acoustic devices of the same type. In another example, the standard or specification can be defined by frequency domain recovered FI data of multiple acoustic wave devices (e.g., an average, or a mean, of the frequency domain recovered FI data for the multiple devices).

FIG. 5B is a flow chart of a time domain recovery method 60 for an acoustic wave device (e.g., a SAW device or resonator, a BAW device or resonator). The method 60 includes the step of performing 61 an EVB test of a first acoustic wave device (e.g., SAW device or resonator, BAW device or resonator) to obtain test data in the frequency domain. The method 60 also includes the step of converting 62 (e.g., using an inverse Fourier transform) the EVB test data for the first acoustic wave device from the frequency domain to the time domain. The method 60 also includes the step of gating 63 (e.g., filtering out, removing) the EM path signal data (e.g., feedthrough/cross-coupling signal) in the time domain from the EVB test data response for the first acoustic wave device to isolate the EM path signal data of the EVB test data response. The method 60 also includes the step of performing 64 an FI test of a second (and all subsequent) acoustic wave device (e.g., a SAW device or resonator, a BAW device or resonator) and obtain test data in the frequency domain. The second acoustic wave device can be of the same type (e.g., similar, identical) as the first acoustic wave device. The method 60 also includes the step of converting 65 (e.g., using an inverse Fourier transform) the FI test data for the second acoustic wave device from the frequency domain to the time domain. The method 60 also includes the step of gating 66 (e.g., filtering out, removing) the EM path signal data (e.g., feedthrough/cross-coupling signal) in the time domain from the FI test data response for the second acoustic wave device to isolate the acoustic path signal data of the FI test data response for the second acoustic wave device. The method 60 also includes the step of adding 67 the isolated EM path signal data (e.g., feedthrough/cross-coupling signal) from the EVB test data response for the first acoustic wave device to the isolated acoustic path signal data of the FI test data response for the second acoustic wave device to thereby obtain time domain recovered FI test data (e.g., an FI test data response with time domain recovery of the EM path signal data from EVB test data for the second acoustic wave device). The method 60 also includes the step of converting 68 the time domain recovered FI data to frequency domain (e.g., using a Fourier transform) to obtain a frequency domain recovered FI test data for the second acoustic wave device. The method 60 includes the step of comparing 69 the frequency domain recovered FI test data against a specification or standard (e.g., test response of one or more previously tested acoustic wave devices). The method 60 also includes the step of judging or determining 70 if the second (and subsequent) acoustic wave device passes (e.g., is approved for delivery to a customer) or fails based on a comparison of its frequency domain recovered FI test data with the standard or specification.

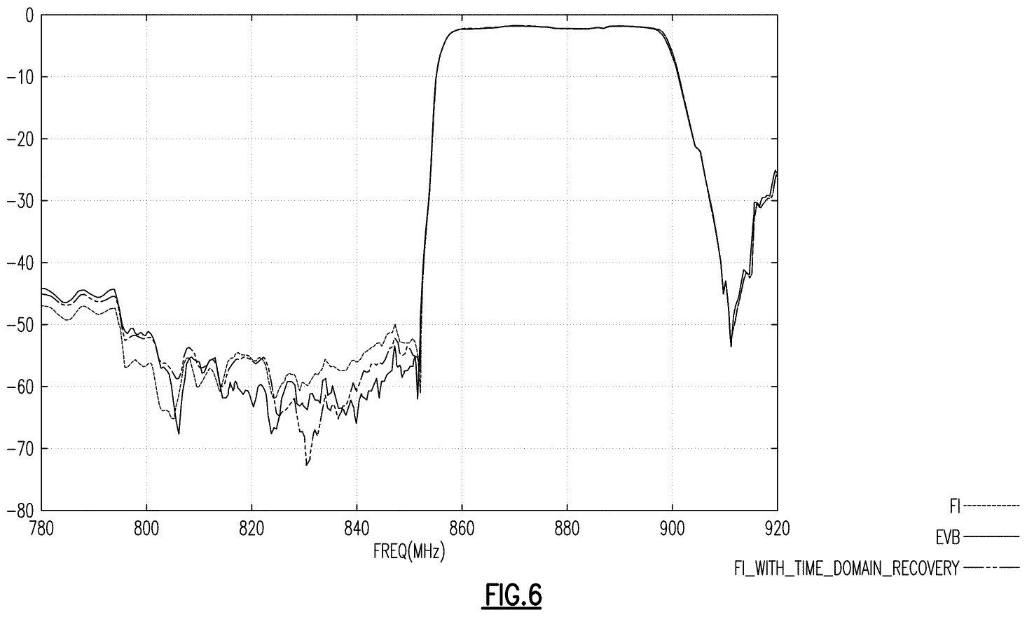

FIG. 6 shows a comparison in the frequency domain for a tested acoustic wave device (e.g., a SAW device or resonator, a BAW device or resonator) of EVB test data (solid line) for said tested acoustic wave device, FI test data (dashed line) for said tested acoustic wave device, and FI test data with time domain recovery of EM path signal from the EVB test (dash-dot-dot-dash line) (e.g., using method 40 or method 60 described above). As shown in FIG. 6, the FI test data with time domain recovery of the EM path signal from an EVB test is similar (e.g., approximates, tracks, correlates with) the EVB test data response, and can therefore be advantageously used to test acoustic wave devices (e.g., SAW device or resonator, BAW device or resonator) to obtain a test data response that can be compared with an EVB test data to determine if the acoustic wave device meets operating specifications (e.g., whether it can be approved for delivery to a customer).

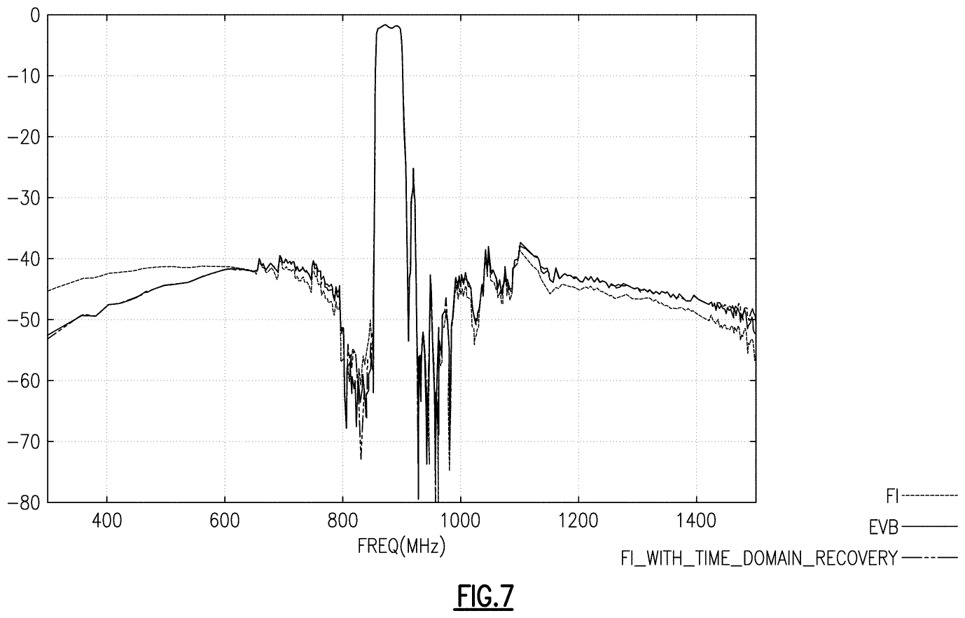

FIG. 7 shows a comparison in the frequency domain for the tested acoustic wave device (e.g., a SAW device or resonator, a BAW device or resonator) in FIG. 6 over a larger frequency scale, of EVB test data (solid line), FI test data (dashed line), and FI test data with time domain recovery of EM path signal from an EVB test (dash-dot-dot-dash line). As shown in FIG. 7, over the larger frequency scale the FI test data with time domain recovery of the EM path signal from an EVB test is similar (e.g., approximates, tracks, correlates with) the EVB test data response.

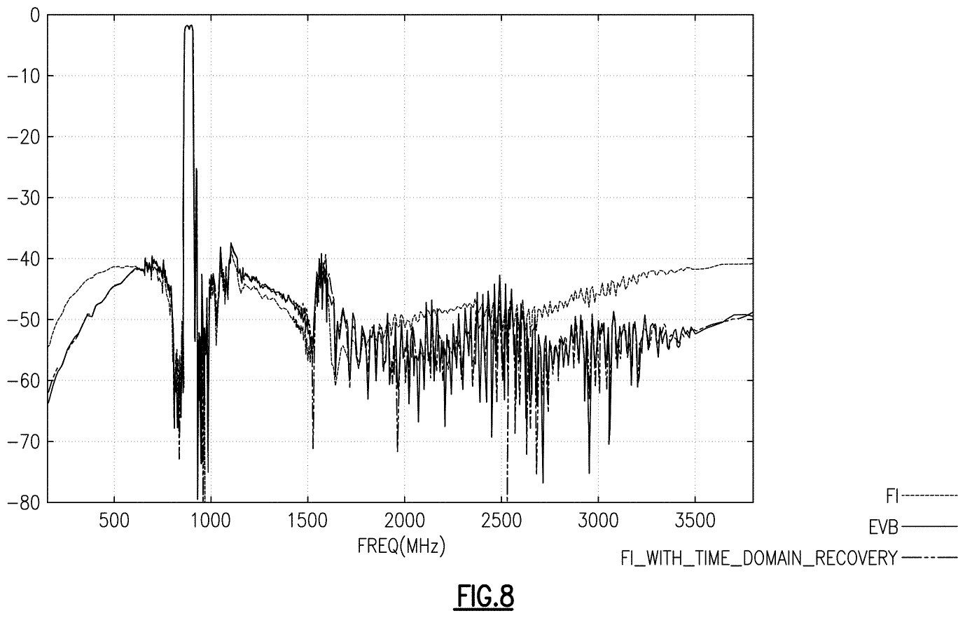

FIG. 8 shows a comparison in the frequency domain for the tested acoustic wave device (e.g., a SAW device or resonator, a BAW device or resonator) in FIGS. 6 and 7 over an even larger frequency scale, of EVB test data (solid line), FI test data (dashed line), and FI test data with time domain recovery of EM path signal from an EVB test (dash-dot-dot-dash line). As shown in FIG. 8, over the larger frequency scale the FI test data with time domain recovery of the EM path signal from an EVB test is similar (e.g., approximates, tracks, correlates with) the EVB test data response.

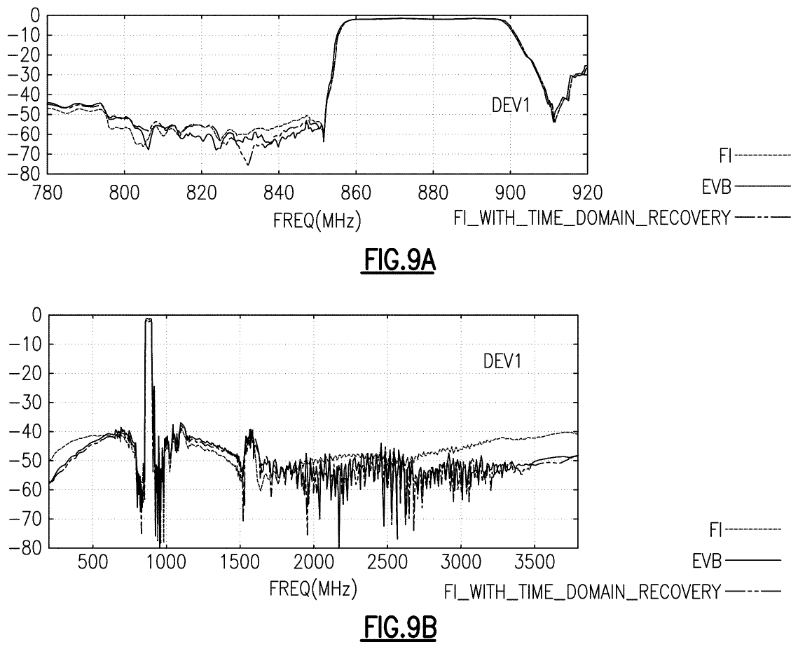

FIGS. 9A-9B show a comparison in the frequency domain (over a shorter frequency range for FIG. 9A and over a longer frequency range for FIG. 9B) for a first acoustic wave device (e.g., a SAW device or resonator, a BAW device or resonator) of EVB test data (solid line) for said first acoustic wave device, FI test data (dashed line) for said first acoustic wave device, and FI test data with time domain recovery of EM path signal from a standard EVB test (dash-dot-dot-dash line) (e.g., using method 40 or method 60 described above). The standard EVB test response in the frequency domain is one previously conducted of a similar (e.g., of the same type, identical) acoustic wave device, against which subsequent acoustic wave devices are compared. As shown in FIGS. 9A-9B, the FI test data with time domain recovery of the EM path signal from a standard EVB test is similar (e.g., approximates, tracks, correlates with) the EVB test data response, both over the shorter frequency range in FIG. 9A and over the longer frequency range in FIG. 9B. Accordingly, the FI test data with time domain recovery of the EM path signal from the standard EVB test can advantageously be used to obtain a test data response that can be compared with EVB test data to determine if the first acoustic wave device meets operating specifications (e.g., whether it can be approved for delivery to a customer).

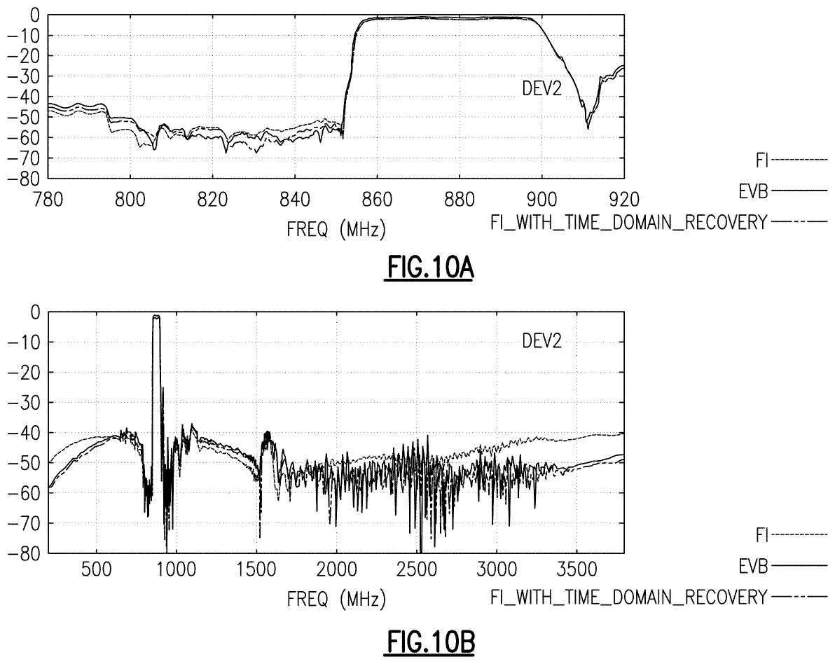

FIGS. 10A-10B show a comparison in the frequency domain (over a shorter frequency range for FIG. 10A and over a longer frequency range for FIG. 10B) for a second acoustic wave device (e.g., a SAW device or resonator, a BAW device or resonator) of EVB test data (solid line) for said second acoustic wave device, FI test data (dashed line) for said second acoustic wave device, and FI test data with time domain recovery of EM path signal from the standard EVB test (dash-dot-dot-dash line) (e.g., using method 40 or method 60 described above). As shown in FIGS. 10A-10B, the FI test data with time domain recovery of the EM path signal from the standard EVB test is similar (e.g., approximates, tracks, correlates with) the EVB test data response, both over the shorter frequency range in FIG. 10A and over the longer frequency range in FIG. 10B. Accordingly, the FI test data with time domain recovery of the EM path signal from the standard EVB test can advantageously be used to obtain a test data response that can be compared with EVB test data to determine if the second acoustic wave device meets operating specifications (e.g., whether it can be approved for delivery to a customer).

As discussed above, the acoustic wave devices (e.g., SAW device or resonator, BAW device or resonator) tested with the methods described herein (e.g., method 40, method 60) can be implemented in a variety of electronics, as described further below.

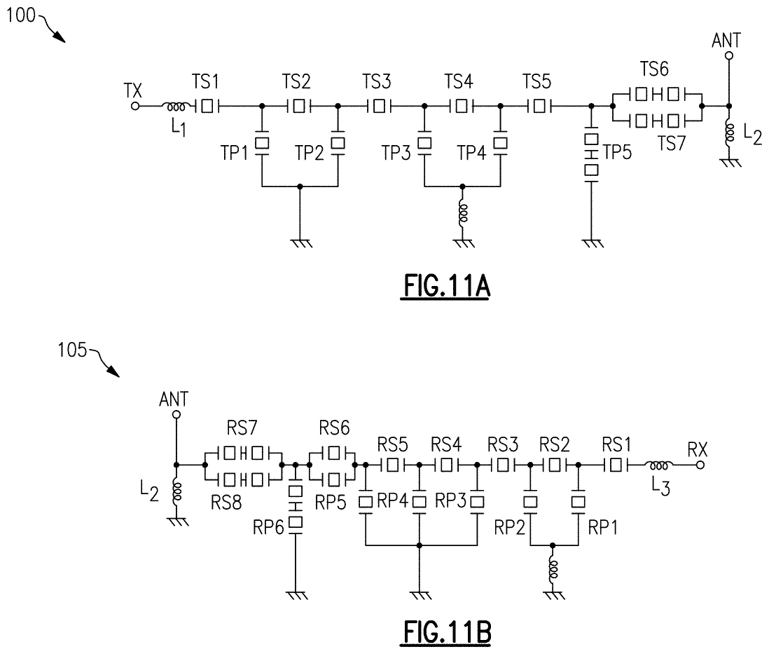

FIG. 11A is a schematic diagram of an example transmit filter 100 that includes surface acoustic wave resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. One or more of the SAW resonators of the transmit filter 100 can be any surface acoustic wave resonator. Any suitable number of series SAW resonators and shunt SAW resonators can be included in a transmit filter 100.

FIG. 11B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. One or more of the SAW resonators of the receive filter 105 can be any surface acoustic wave resonator. Any suitable number of series SAW resonators and shunt SAW resonators can be included in a receive filter 105.

Although FIGS. 11A and 11B illustrate example ladder filter topologies, any suitable filter topology can include a SAW resonator in accordance with any suitable principles and advantages disclosed herein. Example filter topologies, include ladder topology, a lattice topology, a hybrid ladder and lattice topology, a multi-mode SAW filter, a multi-mode SAW filter combined with one or more other SAW resonators, and the like.

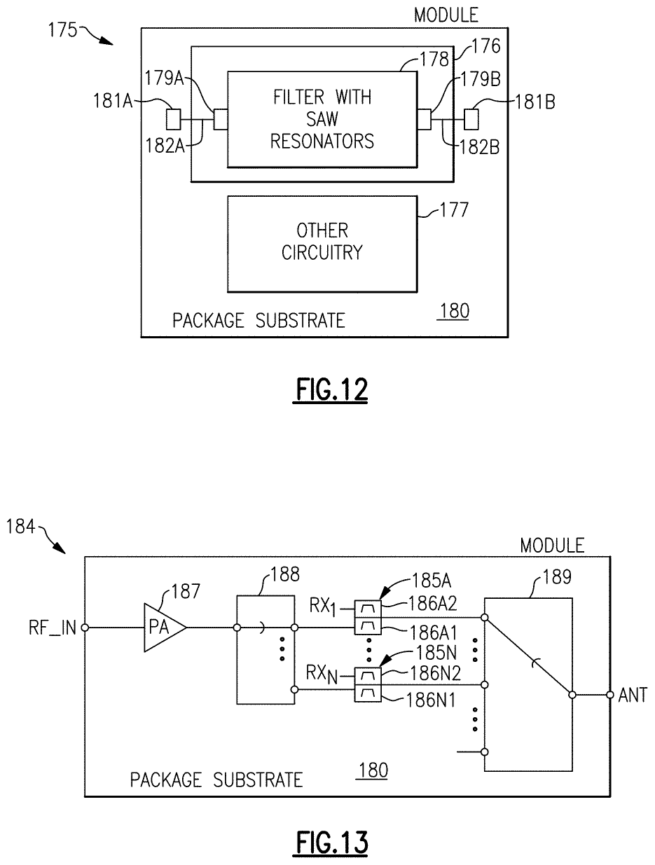

FIG. 12 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators. The SAW component 176 can include a SAW die that includes SAW resonators.

The SAW component 176 shown in FIG. 12 includes a filter 178 and terminals 179A and 179B. The filter 178 includes SAW resonators. The terminals 179A and 178B can serve, for example, as an input contact and an output contact. The SAW component 176 and the other circuitry 177 are on a common packaging substrate 180 in FIG. 12. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 175. The overmold structure can encapsulate some or all of the components of the radio frequency module 175.

FIG. 13 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 13 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

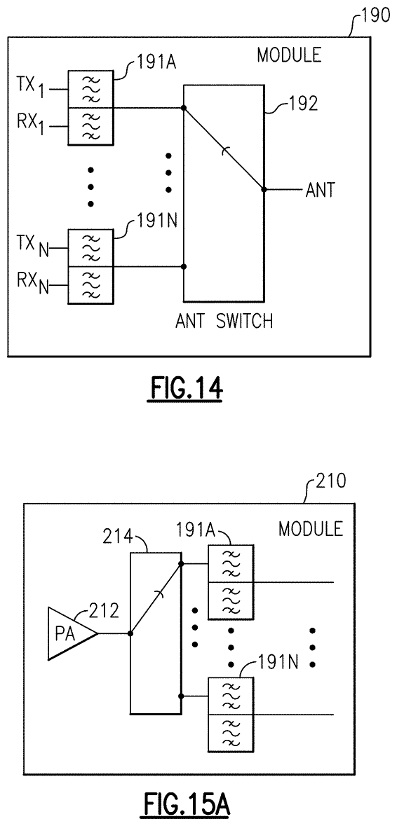

FIG. 14 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

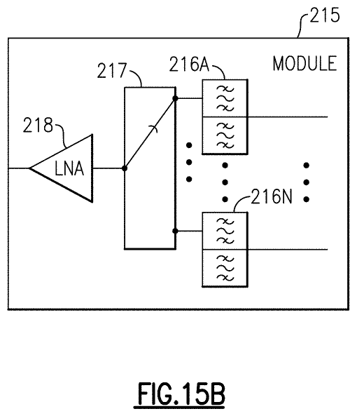

FIG. 15A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 15B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

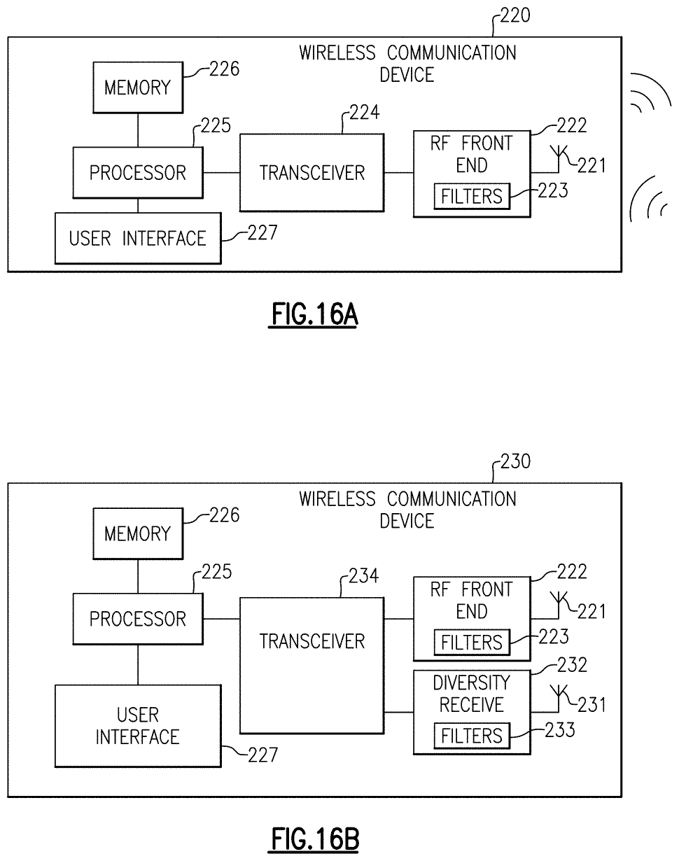

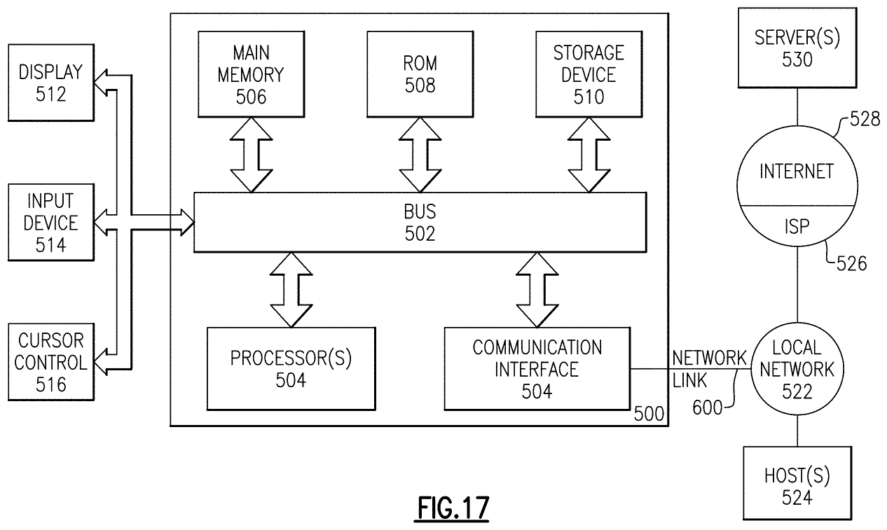

FIG. 16A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 16B is a schematic diagram of a wireless communication device 230 that includes filters 223 in a radio frequency front end 222 and a second filter 233 in a diversity receive module 232. The wireless communication device 230 is like the wireless communication device 200 of FIG. 16A, except that the wireless communication device 230 also includes diversity receive features. As illustrated in FIG. 16B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Although embodiments disclosed herein relate to surface acoustic wave resonators, any suitable principles and advantages disclosed herein can be applied to other types of acoustic wave resonators that include an IDT electrode, such as Lamb wave resonators and/or boundary wave resonators. For example, any suitable combination of features of the tilted and rotated IDT electrodes disclosed herein can be applied to a Lamb wave resonator and/or a boundary wave resonator.

According to an embodiment, the time domain recovery method described herein, such as the method 40 or method 60, may be implemented by one or more special-purpose computing devices. The special-purpose computing devices may optionally be hard-wired to perform the techniques, or may include digital electronic devices such as one or more application-specific integrated circuits (ASICs) or field programmable gate arrays (FPGAs) that are persistently programmed to perform the methods or techniques, or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. The special-purpose computing devices may be desktop computer systems, server computer systems, portable computer systems, handheld devices (e.g., tablet computers, mobile phones), networking devices or any other device or combination of devices that incorporate hard-wired and/or program logic to implement the techniques.

Computing device(s) are generally controlled and coordinated by operating system software, such as iOS, Android, Chrome OS, Windows XP, Windows Vista, Windows 7, Windows 8, Windows Server, Windows CE, Unix, Linux, SunOS, Solaris, iOS, Blackberry OS, VxWorks, or other compatible operating systems. In other embodiments, the computing device may be controlled by a proprietary operating system. Conventional operating systems control and schedule computer processes for execution, perform memory management, provide file system, networking, I/O services, and provide a user interface functionality, such as a graphical user interface (“GUI”), among other things.

For example, FIG. 17 is a block diagram that illustrates an embodiment of a computer system 500 upon which the time domain recovery methods or techniques discussed herein may be implemented. In one implementation, the computer system 500 can be one or more computing devices that process the test data. In one implementation, the computer system 500 can be implemented in electronics of a test device with which the acoustic wave devices are tested.

Computer system 500 includes a bus 502 or other communication mechanism for communicating information, and a hardware processor, or multiple processors, 504 coupled with bus 502 for processing information. Hardware processor(s) 504 may be, for example, one or more general purpose microprocessors.

Computer system 500 also includes a main memory 506, such as a random access memory (RAM), cache and/or other dynamic storage devices, coupled to bus 502 for storing information and instructions (e.g., corresponding to the execution of the method 40 in FIG. 5A or method 50 in FIG. 5B) to be executed by processor 504. Main memory 506 also may be used for storing temporary variables or other intermediate information during execution of instructions to be executed by processor 504. Such instructions, when stored in storage media accessible to processor 504, render computer system 500 into a special-purpose machine that is customized to perform the operations specified in the instructions.

Computer system 500 further may include a read only memory (ROM) 508 or other static storage device coupled to bus 502 for storing static information and instructions for processor 504. A storage device 510, such as a magnetic disk, optical disk, or USB thumb drive (Flash drive), and/or any other suitable data store, is provided and coupled to bus 502 for storing information and instructions, such as sensor data, control instructions and/or the like.

Computer system 500 may be coupled via bus 502 to a display 512. The display 512 can be one of the displays discussed above (e.g., in a tablet computer, laptop computer, desktop computer, etc.) for displaying information to a user and/or receiving input from the user. An input device 514, which may include alphanumeric and other keys (e.g., in a remote control), is optionally coupled to bus 502 for communicating information and command selections to processor 504. Another type of user input device is cursor control 516, such as a mouse, a trackball, cursor direction keys, or otherwise a cursor for communicating direction information and command selections to processor 504 and for controlling cursor movement on the display 512. This input device typically has at least two degrees of freedom in two axes, a first axis (for example, x) and a second axis (for example, y), that allows the device to specify positions in a plane. In some embodiments, the same direction information and command selections as cursor control may be implemented via receiving touches on a touch screen without a cursor.

Computing system 500 may include a user interface module, and/or various other types of modules to implement one or more graphical user interface of the data analysis system. The modules may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “module,” as used herein, refers to a collection of software instructions, possibly having entry and exit points, written in a programming language, such as, for example, Java, Lua, C or C++. A software module may be compiled and linked into an executable program, installed in a dynamic link library, or may be written in an interpreted programming language such as, for example, BASIC, Perl, or Python. It will be appreciated that software modules may be callable from other modules or from themselves, and/or may be invoked in response to detected events or interrupts. Software modules configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression, or decryption prior to execution). Such software code may be stored, partially or fully, on a memory device of the executing computing device, for execution by the computing device. Software instructions may be embedded in firmware, such as an EPROM. It will be further appreciated that hardware devices (such as processors and CPUs) may be comprised of connected logic units, such as gates and flip-flops, and/or may be comprised of programmable units, such as programmable gate arrays or processors. Generally, the modules described herein refer to logical modules that may be combined with other modules or divided into sub-modules despite their physical organization or storage. In various embodiments, aspects of the methods and systems described herein may be implemented by one or more hardware devices, for example, as logic circuits. In various embodiments, some aspects of the methods and systems described herein may be implemented as software instructions, while other may be implemented in hardware, in any combination.

As mentioned, computer system 500 may implement the methods or techniques described herein using customized hard-wired logic, one or more ASICs or FPGAs, firmware and/or program logic which in combination with the computer system causes or programs computer system 500 to be a special-purpose machine. According to one embodiment, the techniques herein are performed by computer system 500 in response to processor(s) 504 executing one or more sequences of one or more modules and/or instructions contained in main memory 506. Such instructions may be read into main memory 506 from another storage medium, such as storage device 510. Execution of the sequences of instructions contained in main memory 506 causes processor(s) 504 to perform the process steps described herein. In alternative embodiments, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 510. Volatile media includes dynamic memory, such as main memory 506. Common forms of non-transitory media include, for example, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 502. Transmission media can also take the form of acoustic or light waves, such as those generated during radio-wave and infra-red data communications.

Various forms of media may be involved in carrying one or more sequences of one or more instructions to processor 504 for execution. For example, the instructions may initially be carried on a magnetic disk or solid state drive of a remote computer. The remote computer can load the instructions and/or modules into its dynamic memory and send the instructions over a telephone line using a modem. A modem local to computer system 500 can receive the data on the telephone line and use an infra-red transmitter to convert the data to an infra-red signal. An infra-red detector can receive the data carried in the infra-red signal and appropriate circuitry can place the data on bus 502. Bus 502 carries the data to main memory 506, from which processor 504 retrieves and executes the instructions. The instructions received by main memory 506 may optionally be stored on storage device 510 either before or after execution by processor 504.

In some embodiments, Computer system 500 may also include a communication interface 518 coupled to bus 502. Communication interface 518 provides a two-way data communication coupling to a network link 600 that is connected to a local network 522. For example, communication interface 518 may be an integrated services digital network (ISDN) card, cable modem, satellite modem, or a modem to provide a data communication connection to a corresponding type of telephone line. As another example, communication interface 518 may be a local area network (LAN) card to provide a data communication connection to a compatible LAN (or WAN component to communicate with a WAN). Wireless links may also be implemented. In any such implementation, communication interface 518 sends and receives electrical, electromagnetic, or optical signals that carry digital data streams representing various types of information. For example, the communication interface 518 can allow the computer system 500 to communicate with the database 338 and/or scanner 340.

Network link 600 typically provides data communication through one or more networks to other data devices. For example, network link 600 may provide a connection through local network 522 to a host computer 524 or to data equipment operated by an Internet Service Provider (ISP) 526. ISP 526 in turn provides data communication services through the world wide packet data communication network now commonly referred to as the “Internet” 528. Local network 522 and Internet 528 both use electrical, electromagnetic, or optical signals that carry digital data streams. The signals through the various networks and the signals on network link 600 and through communication interface 518, which carry the digital data to and from computer system 500, are example forms of transmission media.

Computer system 500 can send messages and receive data, including program code, through the network(s), network link 600 and communication interface 518. In the Internet example, a server 530 might transmit a requested code for an application program through Internet 528, ISP 526, local network 522 and communication interface 518. For example, in an embodiment various aspects of the data analysis system may be implemented on one or more of the servers 530 and may be transmitted to and from the computer system 500. For example, data may be transmitted between computer system 500 and one or more servers 530 (e.g., on which the database 338 may reside). In an example, FI test data and/or EVB test date may be transmitted from a database on the one or more servers 530 to the computer system 500, and analysis data (e.g., gated FI data with time domain recovery of EVB test data) may then be transmitted back to the servers 530 (e.g., to one or more databases on the servers).

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

Of course, the foregoing description is that of certain features, aspects, and advantages of the present invention, to which various changes and modifications can be made without departing from the spirit and scope of the present invention. Moreover, the devices described herein need not feature all of the objects, advantages, features, and aspects discussed above. Thus, for example, those of skill in the art will recognize that the invention can be embodied or carried out in a manner that achieves or optimizes one advantage or a group of advantages as taught herein without necessarily achieving other objects or advantages as may be taught or suggested herein. In addition, while a number of variations of the invention have been shown and described in detail, other modifications, and methods of use, which are within the scope of this invention, will be readily apparent to those of skill in the art based upon this disclosure. It is contemplated that various combinations or subcombinations of these specific features and aspects of embodiments may be made and still fall within the scope of the invention. Accordingly, it should be understood that various features and aspects of the disclosed embodiments can be combined with or substituted for one another in order to form varying modes of the discussed devices.

What is claimed is:

1. A method for testing a performance of an acoustic wave device, comprising:
performing a final inspection test on an acoustic wave device to obtain a test data response in a frequency domain;
converting the final inspection test data response from the frequency domain to a time domain;
gating an electromagnetic path signal of the final inspection test data response to produce a modified final inspection test data response without the electromagnetic path signal; and
adding an isolated electromagnetic path signal from an engineering test data response to the modified final inspection test data response to produce a final inspection test data response with time domain recovery of electromagnetic path signal from the engineering test.

2. The method of claim 1 further comprising comparing the final inspection test data response with time domain recovery of electromagnetic path signal from the engineering test against an engineering test data response of a similar or identical acoustic wave device to determine if the tested acoustic wave device passes inspection.

3. The method of claim 2 wherein determining if the tested acoustic wave device passes inspection includes determining if the final inspection test data response with time domain recovery of the electromagnetic path signal from the engineering test substantially approximates the engineering test data response.

4. The method of claim 1 wherein converting the final inspection test data response from the frequency domain to a time domain with units of the test data response includes performing an inverse Fourier transform on the final inspection test data response from the frequency domain.

5. The method of claim 1 wherein gating of the electromagnetic path signal of the final inspection test data response is performed on said test data response in the time domain.

6. The method of claim 1 wherein said adding the isolated electromagnetic path signal to the modified final inspection test data response is performed on said modified test data response in the time domain.

7. The method of claim 1 wherein the acoustic wave device is a surface acoustic wave device.

8. The method of claim 1 wherein the acoustic wave device is a bulk acoustic wave device.

9. The method of claim 1 wherein the final inspection test is performed with a standard probe.

10. The method of claim 1 wherein the final inspection test is performed with a pyramid probe.

11. The method of claim 1 wherein the final inspection test is performed with a conductive sheet probe card.

12. A method for testing a performance of an acoustic wave device, comprising:
performing an engineering test of a first acoustic wave device to obtain a test data response in a frequency domain with units of the test data response;
converting the engineering test data response from the frequency domain to a time domain;
gating an electromagnetic path signal of the engineering test data response to isolate the electromagnetic path signal of the engineering test data response for the first acoustic wave device;
performing a final inspection test on a second acoustic wave device to obtain a test data response in a frequency domain with units of the test data response;
converting the final inspection test data response from the frequency domain to a time domain with units of the test data response;
gating an electromagnetic path signal of the final inspection test data response to produce a modified final inspection test data response without the electromagnetic path signal; and
adding the isolated electromagnetic path signal of the engineering test data response for the first acoustic wave device to the modified final inspection test data response for the second acoustic wave device to produce a final inspection test data response with time domain recovery of the electromagnetic path signal from the engineering test.

13. The method of claim 12 further comprising comparing the final inspection test data response with time domain recovery of the electromagnetic path signal from the engineering test against the engineering test data response of the first acoustic wave device to determine if the second acoustic wave device passes inspection.

14. The method of claim 13 wherein determining if the second acoustic wave device passes inspection includes determining if the final inspection test data response with time domain recovery of the electromagnetic path signal from the engineering test substantially approximates the engineering test data response for the first acoustic wave device.

15. The method of claim 12 wherein converting the final inspection test data response from the frequency domain to a time domain with units of the test data response includes performing an inverse Fourier transform on the final inspection test data response from the frequency domain.

16. The method of claim 12 wherein gating of the electromagnetic path signal of the final inspection test data response is performed on said test data response in the time domain.

17. The method of claim 12 wherein said adding the isolated electromagnetic path signal to the modified final inspection test data response is performed on said modified test data response in the time domain.

18. The method of claim 12 wherein the acoustic wave device is a surface acoustic wave device.

19. The method of claim 12 wherein the acoustic wave device is a bulk acoustic wave device.

20. The method of claim 12 wherein the final inspection test is performed with a standard probe.

21. The method of claim 12 wherein the final inspection test is performed with a pyramid probe.

22. The method of claim 12 wherein the final inspection test is performed with a conductive sheet probe card.
